(19) United States
(12) Patent Application Publication
(10) Pub. No.: US 2003/0190787 A1
(43) Pub. Date: Oct. 9, 2003

(54) Process for realizing a channel scaled and small body gradient VDMOS for high current densities and low driving voltages

(75) Inventor: Giuseppe Curro', Messina (IT)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics S.r.l., Agrate Brianza (IT)

(21) Appl. No.: 10/319,438

(22) Filed: Dec. 13, 2002

(30) Foreign Application Priority Data
Dec. 14, 2001 (IT) VA2001A000045

(51) Int. Cl. H01L 21/336

(52) U.S. Cl. 438/278

(57) ABSTRACT

A process for fabricating a VDMOS power transistor includes forming a gate overlying at least one channel region in a semiconductor substrate, and forming spacers on a first portion of the semiconductor substrate self-aligned with the gate. A first dopant is implanted into the exposed portion of the semiconductor substrate for defining a body region of the transistor. The first dopant is implanted through a first implant window defined by the spacers. The spacers are removed, and a second dopant is implanted into the first portion of the semiconductor substrate for defining a source region of the transistor. The second dopant is implanted through a second implant window defined by an edge of the gate.

### FIELD OF THE INVENTION

The present invention relates to integrated devices, and in particular, to the formation of a VDMOS device.

### BACKGROUND OF THE INVENTION

The scaling of lateral and vertical dimensions of power VDMOS devices implies a large reduction in the thermal budgets associated with the diffusion processes of the source and body junctions, and to the final processes for increasing the density of the dielectrics and to the eventual annealing. The scaling is necessary to increase the current density per unit of active area in devices driven with gate voltages lower than 5V.

These procedures reduce the length of the diffused channel in VDMOS devices, which corresponds to a reduction in the on-resistance. Moreover, the need for fast devices capable of sustaining currents of about one ampere with relatively low gate drive voltages forces a reduction in the turn-on threshold voltage of the device. This is commonly done by reducing the doping levels of the body in the channel region. An example is the low breakdown voltage devices (20+80V) formed using the so-called “single feature size” technology. These devices are characterized by having a channel perimeter per unit area of up to several tens of cm/mm².

Nevertheless, the reduction of thermal budgets for diffusion of the implanted dopant implies drawbacks that may limit performance of the devices, quality and further scalability. The quality is in terms of stability and reproducibility of certain important parameters, such as the threshold voltage. Among these parameters, the increase of the active body gradient in the channel region is particularly important. This increase is due to the reduction in the concentration of the implanted dopant and in the decrease of the successive thermal budget.

As a consequence, a net increase of the current between the drain and source junctions in a forward blocking condition may take place based upon a premature opening of the channel (i.e., the device is always on). Moreover, given that the threshold voltage in these devices is defined by the peak concentration of the body at the boundary with the source diffusion in the channel region, even a small dispersion or spread in the characteristic of the source junction may cause a large spread in the threshold voltage. Consequently, this results in stability problems when driving the device.

The dimensional tolerances of the structure to be defined in the active area make it very difficult to differentiate the body and source implantation areas when using a dedicated mask. The dimensional tolerances of the structure are a result of the processes for reducing or scaling the dimensions thereof, particularly the channel length. Therefore, a commonly used technique includes reducing the thermal budgets of diffusing the body and source regions.

### SUMMARY OF THE INVENTION

In view of the foregoing background, an object of the present invention is to significantly scale down a VDMOS device, and in particular, to allow a significant reduction in the channel length while ensuring at the same time a low gradient of the concentration of body dopant without reducing the thermal budget for the diffusion.

This and other objects, advantages and features of the present invention are provide by a method in which residues of an isotropic etching of a layer of material deposited with a high degree of conformity over steps (spacers) are exploited for staggering in an easily controllable and a self-aligned fashion the fundamental implantation that determines the characteristics of the body and source regions of a power VDMOS device, without reducing the thermal budget for diffusion of the dopants.

This modification of the common processes for fabricating a power VDMOS structure practically reduces by half the spread of the turn-on threshold voltage of the device, while keeping the same thermal budget for the diffusion of the body and source dopants. The present invention allows the formation of a power VDMOS device with a large ratio channel perimeter/unit of active area. The length of the diffused lateral channel may be controlled by determining precisely the aperture of the body implantation window. This window is defined with conformal sacrificial spacers formed by a deposited and successively etched material self-aligned to the source implantation window.

The above mentioned problems of punch-through of the channel and in the spread of the threshold gate voltage are eliminated or significantly reduced while keeping relatively high the thermal budgets of the diffusion of the body and source junctions. Moreover, the actual value of the threshold voltage may be more precisely defined by adjusting the concentration of the dopant of the body region.

The process steps that specifically implement the invention are introduced in the normal sequence of the fabrication process after having completed definition of a gate oxide layer, and deposition of a polysilicon layer in the active areas.

The steps introduced according to the present invention comprise depositing in a relatively conformal manner a layer of a material suitable for depositing over the steps of the patterned layer of polysilicon along the defined perimeter. The steps also include dry etching in a highly anisotropic manner (directional) the layer of conformally deposited material for forming lateral spacers on the gate structures self-aligned to them, followed by implantation of the body dopant. The sacrificial spacers are then removed and a thermal treatment for diffusing the body dopant is carried out.

The process continues with the formation of the source junction that is aligned to the gate electrode that had been provided with spacers for only implanting the body dopant. The usual sequence of operations for fabricating the VDMOS structure are also performed.

For predetermined thermal processes of body and source diffusion, the dimension of the aperture of the implant window at the base of the sacrificial spacer determines both the channel length as well as the peak concentration of the body dopant in the channel. The width of the spacer at the base and the tolerance range associated with it depends on the thickness and on the relative indetermination of the layer of sacrificial material conformally deposited for forming the lateral spacers on the gate structure.

For VDMOS structures with a channel length between 0.1 and 1.0 μm, the width at the base of the sacrificial spacers may be generally between 0.1 and 0.4 μm. The invention is particularly useful in relatively short channel length devices. In these cases, the order of magnitude of the width of the spacers at the base may be the same as the channel length to be formed.

### BRIEF DESCRIPTION OF THE DRAWINGS

FIG. 1 is a basic sectional view of a VDMOS structure and a graph indicting the concentration profile along the channel in accordance with the prior art;

FIGS. 2 to 10 illustrate the main phases of a fabrication process of a VDMOS device in accordance with the present invention;

FIG. 11 compares the net concentration profiles of the dopant in the channel obtained with a standard process and obtained with the process in accordance with the present invention;

FIG. 12 depicts the effect of the turn-on threshold value as a function of the width of the sacrificial spacer in accordance with the present invention; and

FIG. 13 shows the effect of reducing the dispersion of the threshold value as a function of the width of the sacrificial spacer in accordance with the present invention.

### DETAILED DESCRIPTION OF THE PREFERRED EMBODIMENTS

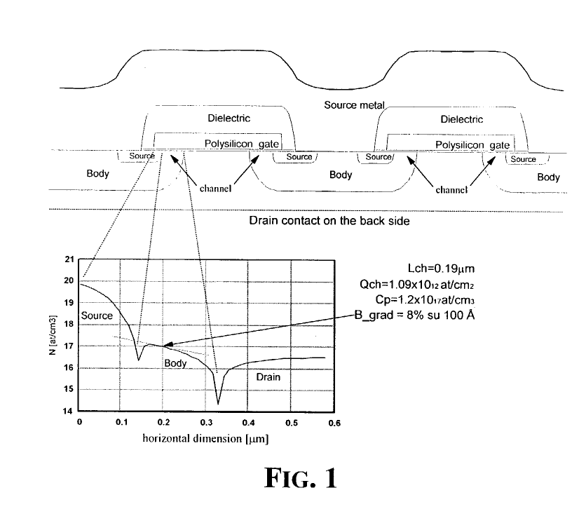

To better understand the effects and results that are obtained with the method of the invention, FIG. 1 depicts a partial basic sectional view of a common VDMOS structure having a relatively large size and a relative concentration profile along the channel. This is for highlighting certain features and critical parameters of such an integrated structure, and their effect on the operating characteristics and performance of the device.

Referring to FIG. 1, the channel of a VDMOS device is characterized by the following. The channel length (Lch) is determined by the source-body junction from one side and from the body-drain junction from the other side. The peak concentration (Cp) is given by the maximum value of the net doping of the channel region. The value of the peak concentration determines the threshold voltage of the device. The higher the peak concentration, the higher the threshold voltage. The charge quantity (Qch) is given by the integral of the net doping inside the channel. The higher this value, the more robust the device is against punch-through. The slope of the body concentration profile (B_grad) is near the peak concentration. The higher this value, the higher the spread of the threshold voltage.

The method of the invention is discussed below in greater detail, and allows formation of channels with a relatively large charge quantity without limiting the scaling down or reduction of the dimensions of the integrated structure. The process of the invention will be illustrated while referring to the formation of a VDMOS structure with a laterally diffused channel.

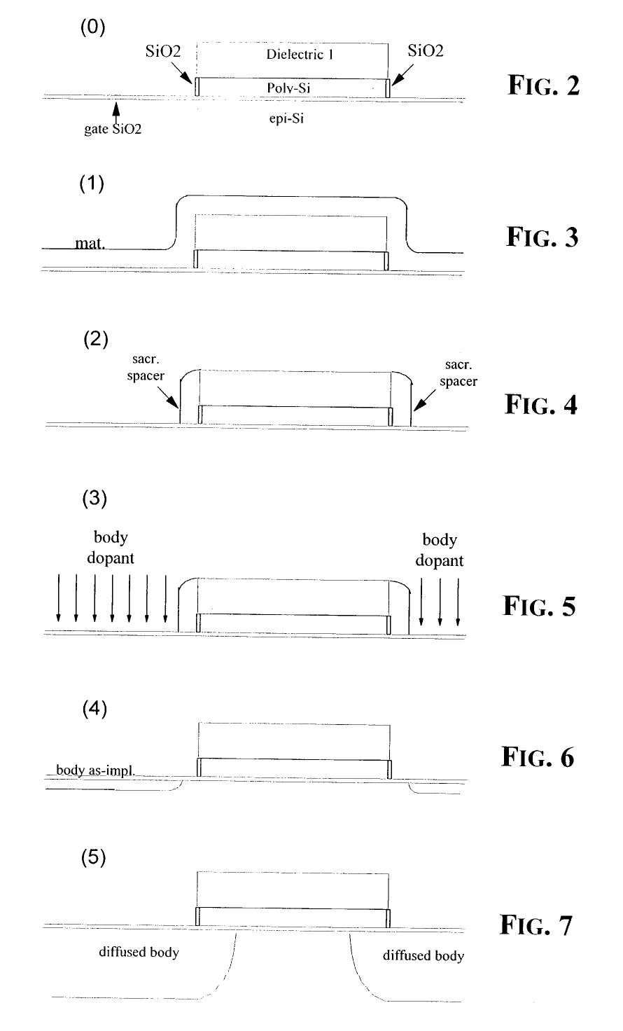

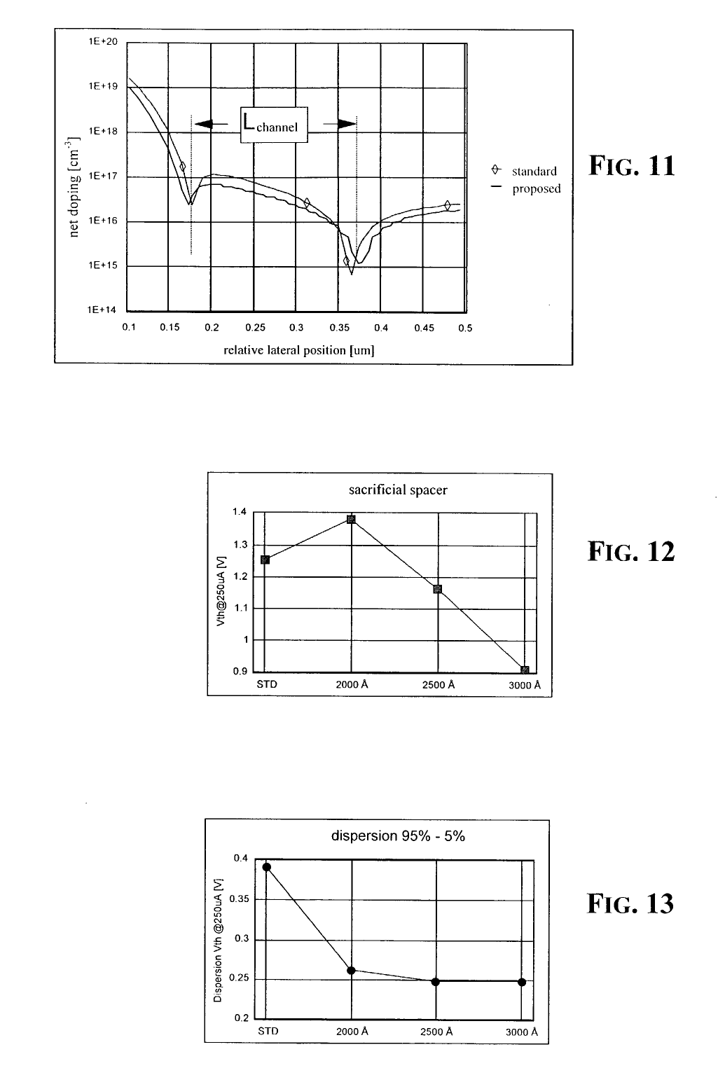

In the following qualitative description reference will be made to FIGS. 2 to 10. The additional process steps that are introduced according to the invention in a VDMOS fabrication process will be distinguished from the commonly known process steps.

The edge structure and the active area of the VDMOS structure are defined on a monocrystalline semiconductor silicon wafer according to commonly used techniques. A dielectric gate oxide layer is grown on the active area. The process further includes depositing and doping a polysilicon gate layer in the active area, and depositing a dielectric isolation layer on the layer of doped polysilicon.

The dielectric isolation layer and the doped polysilicon layer are masked and dry etched for defining a gate electrode structure in the active area. A thin layer of oxide is grown over the etched surfaces for defining the polysilicon gate electrode.

Referring to FIG. 3, a layer of conformally deposited material in accordance with the invention is deposited to form a sacrificial spacer over the oxide definition step surfaces of the polysilicon gate electrode and over the dielectric isolation layer. The thickness of the conformally deposited material is a function of the designed channel length.

Referring to FIG. 4, an anisotropic dry (plasma) etch in accordance with the invention is carried out on the deposited layer of a conformally deposited material having a high etch selectivity. This prevents etching of the materials of the underlying layers in order to form sacrificial spacers along the definition step surfaces of the polysilicon and of the dielectric isolation layer.

Implantation of the body dopant is performed in accordance with the invention, as illustrated in FIG. 5. The dopant is an acceptor for n-channel devices and a donor for p-channel devices. Implantation dosage and energy are chosen as a function of the design threshold voltage.

The process includes removing the sacrificial spacers in accordance with the invention by selectively etching, as illustrated in FIG. 6. A thermal diffusion treatment of the body junction is performed in accordance with the invention, as illustrated in FIG. 7. This is optional in an oxidizing atmosphere (if required). Photolithography is performed for defining the body/source areas of physical contact and the perimeter of the channel region.

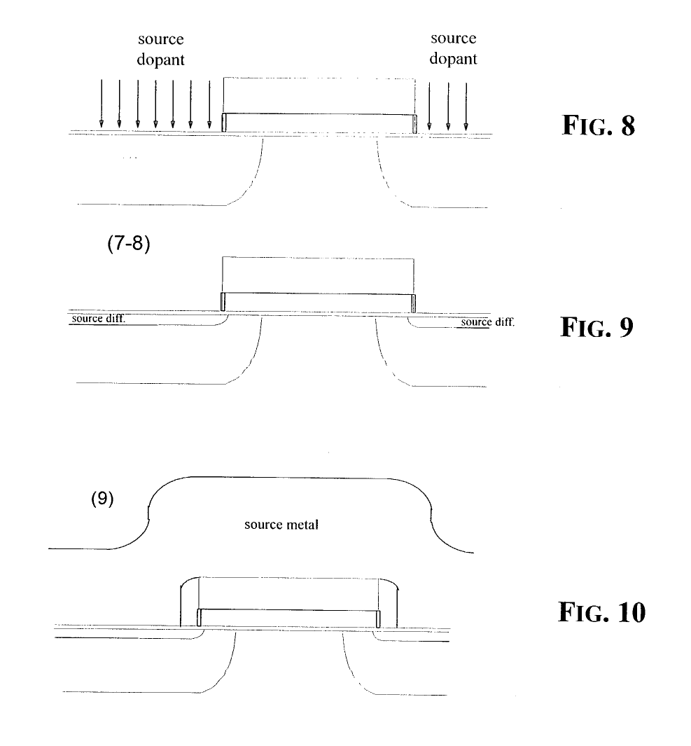

Referring now to FIG. 8, implantation of the source dopant is performed. The dopant is a donor for n-channel devices and an acceptor for p-channel devices. The source junction is diffused by a rapid thermal treatment that is optional in an oxidizing atmosphere (if required). An intermediate dielectric layer is then deposited.

The process further includes making the intermediate dielectric layer more dense. The isolation spacer is etched if required by the integrated structure. The process further includes depositing on the front side a metal layer, and performing a thermal alloying treatment. A metal layer is deposited on the rear side of the wafer.

The choice of the material to be conformally deposited for forming the sacrificial spacers depends on its ability to be selectively etched (definition of the sacrificial spacer and its successive removal). This is in addition to its ability to be deposited with a high degree of conformity over the gate definition steps. This is necessary to preserve the integrity of the other layers during the etchings.

Of course, etching of the sacrificial spacer may alternatively be carried out after the body diffusion if it does not compromise the selective etch. According to another possible alternative, the body and source junctions may be co-diffused with a single thermal treatment.

Appropriate materials to form sacrificial spacers may be silicon oxide deposited in a high conformal mode by a low pressure, chemical vapor deposition (LPCVD), or even more preferably for the reasons that will be highlighted below by using an intrinsic polycrystalline silicon (polysilicon), i.e., an undoped polysilicon.

Preferably, the material used for the formation of the sacrificial spacers is the intrinsic polysilicon, which is deposited in an oven according to a LPCVD process. By using polysilicon, the integrity of the underlying polysilicon gate and the integrity of the epitaxial silicon may be easily ensured during the steps of forming and removing the sacrificial spacers based upon the presence of thin thermal silicon oxide layers.

More precisely, the residual gate oxide layer present on the monocrystalline silicon forms an effective barrier towards the underlying epitaxial silicon. A thin film of silicon oxide may also be grown on the definition edges of the polysilicon gate to protect it during the etching of the sacrificial layer of the intensive polysilicon with which the spacers are formed. Obviously, other materials that can be deposited in a highly conformal mode and that can be selectively etched may be used for forming the sacrificial spacers.

The result that is obtained with the process of the invention is depicted in FIG. 11, in which the diffusion body profiles in the channel zone relative to two devices of the same channel length (about 0.3 μm) are compared. One device (standard) is formed with a standard process (a single body and source implantation, and body diffusion at a low thermal budget), and the other is formed with the process in accordance with the invention (body and source implantation windows distinct but self aligned, and an unscaled thermal budget for the body diffusion).

The above comparison is only an example of the results that may be obtained by arbitrarily choosing implantation and body diffusion parameters in a simulation of a device formed with the process in accordance with the invention. It may be noted that by increasing the implantation dose of the body and/or the diffusion thermal budget, it is possible to restore the peak concentration value to the value of the standard reference device, while at the same time reducing further the concentration gradient.

The results that may be obtained with the process of the invention for a low voltage and a low threshold VDMOS device are outstanding in terms of the spread of the threshold voltage. FIGS. 3 and 4 respectively show diagrams of the mean threshold voltage Vth and the spread thereof, defined as the width between 5% and 95% of the distribution of the parameter.

A device fabricated with the standard process with a low thermal body diffusion budget (STD) is compared with devices fabricated according to the process of the invention. That is, the body diffusion is performed at a higher temperature and at a longer time, but with a body implantation window that is restricted by the polysilicon sacrificial spacers of different dimensions.

By increasing the body diffusion thermal budget while restricting the implantation window of the body dopant with a spacer of about 2400 Å, the threshold voltage is practically unchanged and at the same time, the spread (at wafer-level) of the same parameter is reduced significantly from at least 30% to almost 50%.

The process of the invention produces a net reduction of the ratio between the distance the lateral diffused body region extends (with respect to the definition edge of the polysilicon gate) and the depth of the diffused body region. By way of example, the above ratio is reduced by about 50% for a 7000 Å deep diffusion formed according to standard processes that give a ratio between lateral extension/depth of about 80% by using a sacrificial spacer with a width at its base of about 2400 Å.

That which is claimed is:

1. A process of fabrication of a VDMOS power transistor comprising the operations of forming edge structures and defining the active area of the integrated structure of the transistor on a monocrystalline semiconductor substrate, growing a gate oxide layer on the silicon in the active area, depositing a polycrystalline silicon layer and doping the same on the gate oxide layer in said active area, depositing a dielectric isolation layer on said polycrystalline silicon layer, photolitographically forming a mask and dry etching said dielectric isolation layer and said polycrystalline silicon layer defining a gate structure in said active area, characterized in that it further comprises
depositing a sacrificial layer of a material deposited with a high degree of conformity over said defined gate structure,
dry etching anisotropically the material of said conformally deposited layer forming spacers over the definition surfaces of said gate structure,
implanting a body dopant through the implant window aperture defined by said spacers, into said monocrystalline semiconductor substrate,
removing by a dry etch said spacers and diffusing the implanted body dopant continuing the process in a known manner through the steps of implanting source dopant through the implant window aperture defined by the definition surfaces of said gate structure, diffusing the implant source dopant, depositing an intermediate dielectric layer optionally carrying out a densification treatment thereof, masking and etching for opening contacts, metallizing the front side and the rear side of the silicon semiconductor wafer.

2. The process according to claim 1, characterized in that the material conformally deposited of said sacrificial layer is undoped polysilicon.

3. The process according to claim 1, characterized in that the diffusion of the implanted body dopant is carried out before removing said sacrificial spacers.

4. The process according to claim 1, characterized in that the diffusion of the implanted body dopant is carried out together with the diffusion of the implanted source.

5. The process according to claim 1, characterized in that the width of said spacers at their base is comprised between 0.1 and 0.4 μm.
